(19) United States
(12) Patent Application Publication
(10) Pub. No.: US 2010/0012819 A1
(43) Pub. Date: Jan. 21, 2010

(54) Optical Power Beaming to Electrically Powered Devices

(76) Inventor: David S. Graham, Mountain View, CA (US)

Correspondence Address: FENWICK & WEST LLP, SILICON VALLEY CENTER, 801 CALIFORNIA STREET, MOUNTAIN VIEW, CA, 94041, US

(21) Appl. No.: 12/519,151

(22) PCT Filed: Jan. 24, 2007
(86) PCT No.: PCT/US07/61007

§ 371 Date: Jun. 12, 2009

Related U.S. Application Data
(60) Provisional application No. 60/866,807, filed on Nov. 21, 2006.

(51) Int. Cl. G01D 5/30; H01L 31/04; G01N 21/47

(52) U.S. Cl. 250/205; 250/216; 250/237 R; 356/445

(57) ABSTRACT

In one embodiment, a transmitter assembly containing a light source is electrically powered. The light source receives electrical power and converts the electrical power to an optical power beam that is directed through free space to an optical-to-elect power converter for a device. The optical-to-electric power converter converts the optical power beam to electrical form, thus providing electrical power to a device. A safety subsystem assures that the emission beyond the hot zone between the transmitter and receiver do not exceed regulatory levels.

### RELATED APPLICATIONS

This application claims priority from the U.S. provisional patent application Ser. No. 60/866,807 entitled “Reflection-Safe Receiver for Power Beaming”, filed Nov. 21, 2006, the disclosure of which is incorporated herein by this reference.

### BACKGROUND OF THE INVENTION

1. Field of the Invention

This invention relates to free space optical transmission of power to electrically-powered devices.

2. Description of the Related Art

Common home and business electrical and electronic devices typically receive power from five types of sources: (1) wall outlets, (2) other electrical devices, (3) rechargeable batteries, (4) disposable batteries, and (5) solar cells.

First, many common home and business electrical and electronic devices are plugged into wall outlets. An example is a lamp with a power cord. The length of the cord limits how far away the lamp can be placed from the outlet. The cord can get tangled or become a trip hazard. The cord may be unsightly. Moreover, there may be insufficient outlets for all of the devices requiring power.

Second, some common home and business devices are plugged directly into another device. An example is a stereo speaker plugged into a stereo. In this case, although the speaker need not be plugged into an outlet, a wire still connects the stereo to the speaker, which results in similar disadvantages as described above (i.e., tangling, trip hazard, and unsightliness). In addition, systems that require one device to be plugged into another device often involve a costly, difficult installation. To move one or both of the devices later is made complicated by the fact they must be connected by a wire or cord.

Third, some common home and business devices are operated by rechargeable batteries. Examples include electric shavers, cordless drills, and cell phones. These devices still require power for recharging from an outlet. Again, there may be more chargers than convenient outlets, and batteries may run out at inconvenient times during use.

Fourth, some common home and business devices are operated by disposable batteries. Travel alarm clocks and portable radios often operate this way. These devices tend not to be very powerful. Also, over time, the batteries must be replaced.

Fifth, a few devices are powered by solar cells. For example, pocket calculators are commonly powered by solar cells. These devices also tend not to be very powerful. Because of the power limitations, solar cells are rarely used to power devices.

Currently, to the inventor's knowledge, no completely cordless solution for power to common home and business devices is available.

In some experimental situations, scientists have attempted to transmit power through free space. For example, in the early 20^{th} century, Nicola Tesla wanted to send power over the air in large amounts, but he did not succeed. See http://www.pbs.org/tesla.

As another example, NASA has done experiments to transmit microwave power to a rectenna. The rectenna, or rectifying antenna, outputs DC electricity. See http://www.kurasc.kyoto-u.ac.ip/plasma-group/sps/history2-e.html. Microwaves have at least four substantial disadvantages as compared to lasers. First, microwave emitters, as intentional emitters under Federal Communications Commission regulations, require licensing and bandwidth. Second, they can cause signal interference and, because they operate within a regulated spectrum, any unwanted reflection will cause interference. Third, microwave components generally are not as easy to manufacture and work with as optical components. Fourth, microwave emitters can be unsafe around people; microwave radiation can cause burns and is linked to cancer.

For more detail on microwave systems, please refer to the following patents: Remote piloted vehicle powered by beamed radiation, U.S. Pat. No. 6,364,253; Microwave-powered aircraft, U.S. Pat. No. 5,503,350; Power-beaming system, U.S. Pat. No. 5,068,669; Dual Polarization Reception and Conversion System, U.S. Pat. No. 4,943,811; and Orbiting Solar Power Station, U.S. Pat. No. 4,078,747.

NASA has used lasers to power a small model airplane as part of its studies of beaming power from space to earth and of keeping planes aloft for long periods of time. See http://www.nasa.gov/centers/dryden/news/FactSheets/FS-087-DFRC.html. To do this, the experimenters placed a 1 kW laser on a swivel and manually tracked a model airplane on a tether. They used non-eye-safe lasers in a manner that would not be safe or effective in a commercial application. These methods had no way to account for where the optical energy went, or if it was within FDA permitted limits.

For more detail on laser or optical systems, please refer to the following patents:

Optically powered remote microdevices employing fiber optics (U.S. Pat. No. 5,602,386) shows that devices can be powered at a distance by lasers. This system, however, requires that the device be connected to the laser by an optical fiber. Similar systems are sold by JDS-Uniphase, Inc.

Wireless power supply method (U.S. Pat. No. 6,635,818) uses a visible light to drive a small micromachine. It does not provide sufficient power to drive a large load, like an audio speaker. It is not at an eye-safe wavelength. It does not have a system to assure that the human exposure remains within regulatory limits. It does not show a means of delivering the optical power beam to the photovoltaic cell.

Methods and apparatus for beaming power (U.S. Patent Application 2002/0046763) shows a system for beaming light to an airplane or other object. The apparatus includes a laser on a gimble, as demonstrated by NASA. It is not suitable for use in a home or business because it lacks precautions to prevent injury to the unprotected eyes of nearby humans, and because it has no means to avoid being blocked generally. Direct line of sight between a power transmitter and an object is often not available in a home or business.

The system described in U.S. Pat. No. 7,068,991 lacks a safety subsystem. As a result, if a human interferes with the path of the power beam, there is no mechanism to prevent his exposure from exceeding regulatory limits. It is further unsafe because reflections from the surfaces that receive the light are unconstrained and are likely to cause human exposure in excess of regulatory limits.

### SUMMARY

Aspects of the present invention include apparatus and method to optically transfer power through free space in a way that is safe for use in a location, such as an average household or office, with people present who are not taking safety precautions.

In one embodiment, a transmitter assembly containing a light source is electrically powered. The light source receives electrical power and converts the electrical power to an optical power beam that is directed through free space to an optical-to-electric power converter of a device, also referred to as a receiver. The optical-to-electric power converter converts the optical power beam to electrical form, thus providing electrical power to a device. A safety subsystem assures that no human in the vicinity of the transmitter and receiver receives radiation in excess of regulatory limits, even when the optical surfaces are contaminated or dirty, or under other similar real-world conditions.

The optical power beaming system can reduce or eliminate the danger that a human will be harmed by entering the beam path or by receiving stray reflections generated from surfaces of system components or contaminants within the system. In one embodiment, the power beaming system includes: (1) a beam guard to prevent humans and other objects from contacting the optical power beam directly; (2) a transmitter assembly and optical-to-electric power converter that are designed to reduce reflections outside of beam path by using a diffusion layer, a baffle and/or a retroreflector; and (3) a safety subsystem that protects humans in cases of non-ideal events, including contamination, misalignment, and other similar circumstances. Safeguards (1) and (2) may be sufficient for system designed for operation in a clean, well-managed environment. However, (3) ensures that in the event of contamination, misalignment, or other similar circumstances, humans in the vicinity of the optical power beam system are not exposed to reflected optical radiation that escapes the system in excess of established regulatory limits.

In one embodiment, the transmitter assembly includes a camera to search for the optical-to-electric power converter. When it finds a possible optical-to-electric power converter, the transmitter assembly attempts to handshake with the optical-to-electric power converter. In one approach, the handshake includes a series of light pulses from the transmitter assembly and a series of light pulses from a small photodiode of the receiver. Other handshake methods are also possible.

After a successful handshake, the safety subsystem performs operations in an optical power accounting process to assure that the transmitter assembly is safe to illuminate the optical-to-electric power converter. For example, the optical power accounting process may try to account for optical power that leaves the transmitter assembly but is not received at the optical-to-electric power converter nor reflected back to the transmitter. That optical power, if unaccounted for, may cause injury to humans. If the optical power accounting signals a safe condition for transmission, the lasers are turned on for normal operation. The optical power accounting process executes continuously to ensure that the safe condition is maintained. If there is a breach of the safe condition, corrective and/or safety measures are taken. For example, the lasers may be switched off quickly enough to avoid possible injury to humans.

In one implementation, the safety subsystem is partially located at the transmitter assembly and partly at the optical-to-electric power converter. For example, a photodetector may monitor back-reflections off optics at the transmitter assembly, thus indirectly monitoring the transmit power of the optical power beam. A beamsplitter can also be used. At the optical-to-electric power converter, a current and/or voltage detector may monitor the current and/or voltage, respectively, produced by the optical-to-electric power converter, thus indirectly monitoring the receive power of the optical power beam. This measurement can be communicated to the transmitter assembly by a back information channel from a signaling device at the optical-to-electric power converter to a signal receiver at the transmitter assembly. In one implementation, the receiver device has a light source, such as an LED or VCSEL with optics to propagate a signal back along the beam path, and the transmitter has a photodiode with optics creating a field of view along the beam path to the receiver. In one approach, the optical power beam automatically times out (and turns off) unless it periodically receives a signal to stay on from the optical-to-electric power converter.

Advantages of various embodiments of this invention include the following: (a) to safely provide power without cords or cables to common devices; (b) to remove the inconvenience of battery charging and battery charging stations; (c) to reduce the congestion of wall outlets; and/or (d) to provide signal along with power by the same channel. In some embodiments, advantages of this invention include the convenience and aesthetic values as compared to attaching devices to outlets with wires. In some embodiments, the invention also enables new applications, such as lights made from balloons, with no attachment to any surface, clothes with built-in heating and cooling systems, and various other applications and devices that require power, but for which traditional methods of supplying power are undesirable.

Other aspects of the invention include components of the devices described above, and systems using these devices. Other aspects include methods corresponding to any of the foregoing.

### BRIEF DESCRIPTION OF THE DRAWINGS

FIG. 1A is a flow chart of a method of operation of the power beaming system, in accordance with one embodiment.

FIG. 1B shows an example of a power accounting method, in accordance with one embodiment.

FIG. 1C shows an example method of determining areas with omidirectional scattering or directional reflection, in accordance with one embodiment.

FIG. 2 shows a schematic diagram in accordance with one embodiment of the system.

FIG. 3 shows a schematic diagram in accordance with another embodiment of the system.

FIG. 4 shows an example of an indicium on the front surface of the optical-to-electric power converter, in accordance with one embodiment.

FIG. 5A shows an optical power beaming system including guard beams, in accordance with one embodiment.

FIG. 5B shows an example arrangement of guard beam components around the optics of a transmitter assembly, in accordance with one embodiment.

FIG. 5C shows a taxonomy of beam guards used in accordance with some embodiments.

FIG. 6A illustrates an arbitrary surface.

FIG. 6B illustrates the arbitrary surface of FIG. 6A divided into events, in accordance with one embodiment.

### DETAILED DESCRIPTION OF THE PREFERRED EMBODIMENTS

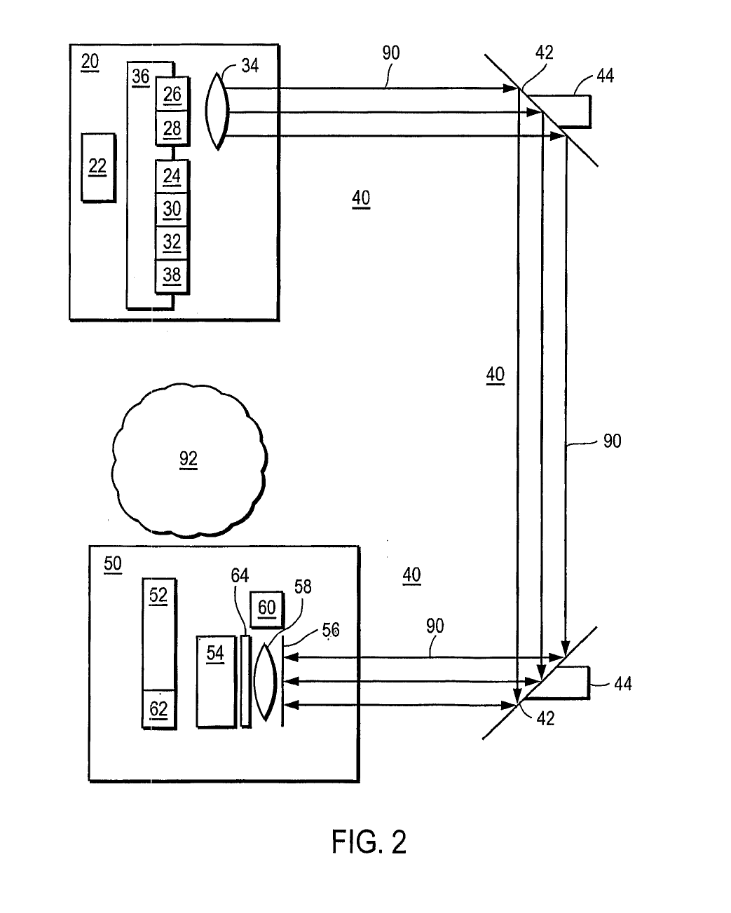

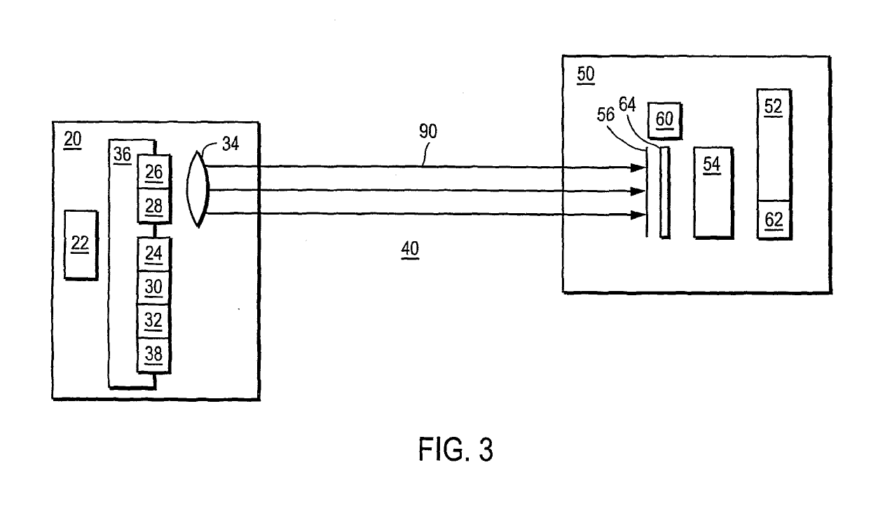

As shown in the examples of FIGS. 2 and 3, one embodiment of the wireless power beaming system includes a transmitter assembly 20, a free space optical path 40, and an optical-to-electric power converter 50 for the device being powered. Transmitter assembly 20 converts electricity to light 90. The light 90 travels through free space 40 to an optical-to-electric power converter 50.

In one embodiment, the transmitter assembly 20 can include a high-efficiency, eye-safe, light source 26 to transmit power; lens(es) 34 and pointing mechanism 36 for focusing and aiming the lasers; and a CPU 22. For example, a laser light source 26 can operate at wavelengths greater than 1400 nm. Examples of such lasers are made by nLight Photonics, Inc, Princeton Lightwave, Covega, and other manufacturers. Light 90 from the laser(s) 26 passes through lens(es) 34 for focusing and aiming the lasers. In a preferred embodiment, the outgoing light 90 is nearly collimated, has a substantially uniform profile, and the beam intensity is 1 mW/sq. mm-10 mW/sq.mm, for example.

To aim the outgoing light 90, a pointing mechanism 36 within the transmitter assembly 20 can be used. In one embodiment the pointing mechanism 36 is a two-axis mechanical system such as a mechanical pan-and-tilt operated by knobs that can be adjusted to aim the outgoing light 90 and then locked in place. Optionally, a visible alignment laser 38 can be used to facilitate aiming and alignment of the system. A collimated beam from the indicator laser 38 travels parallel to the path of light 90. Thus, when the user sees the beam from the visible indicator laser 38 is properly aligned to intersect the optical-to-electric power converter 50, the light source 26 is also properly aligned. Alternatively, the mechanism 36 for focusing and pointing the lasers can be a two-axis mechanical system driven by motors that is powered and controlled from the CPU 22. For example, the mechanism 36 can be a powered pan-and tilt system. Alternatively, a pan and tilt mechanism 44 can manipulate a mirror 42 to direct the light, as described below.

The optical power beaming system shown in FIGS. 2 and 3 can be implemented with a variety of safeguards. These safeguards prevent human exposure to dangerous levels of optical radiation both through preventing humans from directly intercepting the beam should they enter the beam path and through preventing stray reflections generated from surfaces of system components or contaminants within the system.

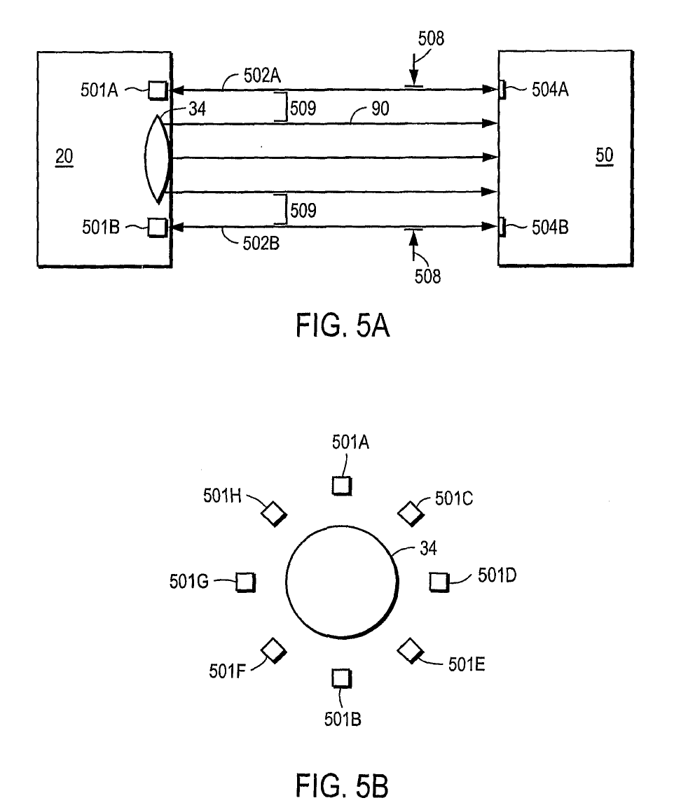

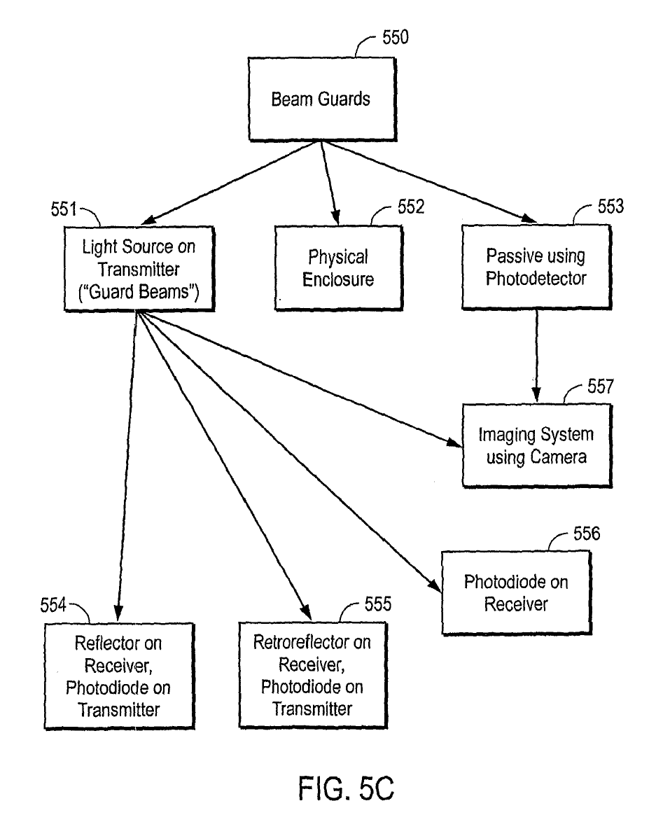

For example, in some implementations, the power beaming system includes a beam guard positioned around the power beam 90. The beam guard detects objects that enter the path of the beam guard. One example of a beam guard, shown in FIGS. 5A and 5B is a series of guard beams 502 positioned around the power beam 90. An optical beam of lower power density than the power beam 90 is generated by each respective light transceiver 501, and is directed to propagate parallel to power beam 90. The guard beams 501 reflect from respective reflectors 504 positioned around the exterior of the optical-to-electric converter 50, to return light to light transceivers 501.

The ring of guard beams 501 forms a protected approximately cylindrical area, the width of which is shown by arrows 508. The protected area includes the path of the power beam 90 plus a reasonable adjacent buffer area 509 between the power beam 90 and the guard beams 501 that extends the entire length of the distance between the transmitter assembly 20 to the optical-to-electric converter 50. This protected area will be referred to herein as the hot zone. In some embodiments, depending upon the configuration of the beam guards, the hot zone may have a cross-section that is a square, rectangular, oval, or any other closed shape. The guard beams 501 are used to detect when an object attempts to enter the hot zone from outside of the hot zone.

When an object enters the path of a guard beam 502, the respective transceiver 501 registers the intrusion and can signal the CPU 22 to turn off the lasers 26, or, at a minimum, not to continue to turn them on. The number, shape, and positioning of guard beams 502 can vary depending upon the application. The purpose of the beam guard is to prevent the power beam from coming into contact directly with objects that may enter the hot zone from time to time.

The beam guards shown in FIGS. 5A and 5B are merely examples; other forms of beam guards are also possible. FIG. 5C shows a taxonomy of some different kinds of beam guards 550. As general categories, a beam guard 550 may have a light source on the transmitter 551 which creates guard beams, a beam guard may be a physical enclosure 552 such as a conduit, or a beam guard may be formed by passively using a photodetector 553. Within the category of beam guards 550 that use a light source on the transmitter 551, two types have a photodiode on the transmitter, one of which has a reflector on the receiver 554, and one of which uses a retroreflector on the receiver 555. Alternatively, the photodiode may be on the receiver 556. An imaging system using a camera 557 can function as a beam guard 550 either with a light source on the transmitter 551 or without one. A camera 557 can act as a beam guard 550, provided its field of view contains the entire beam path. In this case, the illumination values seen at the pixels change in response to the introduction of a foreign object into the field of view of the camera.

Another form of safeguard that can be implemented is designing the transmitter assembly 20 and the optical-to-electric power converter 50 to reduce reflections outside of the beam path by using a diffusion layer, a baffle, or a retroreflector, as described in detail in co-pending provisional patent application Ser. No. 60/866,807 entitled “Reflection-Safe Receiver for Power Beaming”, filed Nov. 21, 2006, which has been incorporated herein by reference. Briefly, an intentional scattering medium such as a diffusion layer is added to the power beam receiver so that parallel light rays incident on the front surface of the power beam receiver are scattered through a series of angles. As a result, any light escaping the system is diffused. The power conversion elements to the power conversion elements of an optical-to-electric power converter can be arranged to reflect incident light into a baffle, in accordance with one embodiment. In this embodiment, the power receiving element can be tilted with respect to the incoming beam. Thus, all light reflected from its surface is trapped by a baffle. Baffles can be made of any material that overwhelmingly absorbs light at least at the wavelength at which the system operates. Example materials include black anodized aluminum or a rigid material covered in a light-absorptive cloth. Alternatively, a series of small, hollow anti-reflection coated corner cube retroreflectors can be placed before the power receiving elements. Reflections from the surfaces of the corner cube retroreflectors, due to contaminants (oil, water, etc.) for example, are reflected safely back along the path to the transmitter assembly 20. It is preferable to use hollow rather than solid retroreflectors because oil or water on the flat surface of a solid retroreflector will cause it to stop retroreflecting and starts reflecting directionally where against the normal, the angle of reflection is opposite the angle of incidence. On a hollow retroreflector, the oil or water may simply increase the retroreflection.

One factor that influences which safeguards are incorporated into the design of the transmitter assembly 20 and the optical-to-electric power converter 50 is whether the angle between the receiver and the power beam is fixed. If the angle is fixed, then a baffle and one or more angled photodiodes provide less area from which light can escape the receiver than a retroreflector and flatphotodiodes, especially under conditions of contamination. A diffusion layer can also be used when the angle is fixed, but it often does not significantly improve safety. If the angle is not fixed, then a retroreflector and one or more flat photodiodes are beneficial because they accept light from many angles. However, the area from which light can be reflected is large relative to the baffled design. In these designs, a diffusion layer can help reduce reflection from the back surface of the retroreflector or the front surface of the photodiode(s).

Still another form of safeguard that can be implemented additionally or alternatively to the above is a safety subsystem that ensures that humans in the vicinity of the optical power beam system are not exposed in excess of established regulatory limits to reflected optical radiation that escapes the hot zone of the system. In operation, steam, dust, or another contaminant may enter the beam path but be too fine to be caught by the beam guard. Such contaminants in the beam path may cause reflections of the beam to areas outside of the hot zone. During regular operation, scratches, dust, condensation, or the like, is likely to accumulate on the surfaces of the system which may also unintentionally cause light to be reflected outside of the hot zone. Although an active mirror can compensate for some movement of system components over time, the system may vibrate or creep such that the beam becomes misaligned with the receiver, which may also lead to radiation that escapes the hot zone of the system. In any of these circumstances, a system that is within specification for safety and efficiency when it ships from the factory may fall out of specification over time. A safety subsystem is used to determine when conditions have deteriorated such that continued operation of the system would pose a danger to humans in the vicinity of the optical power beam system. Various embodiments of a safety subsystem are described below.

As shown in the example embodiments of FIGS. 2 and 3, the wireless power beaming system includes a safety subsystem. The safety subsystem in this example includes a camera 24, such as a CMOS VGA camera from Kodak with a single plastic lens; an illumination light source 30 that points along the same path as the camera 24; a signal receiving photodiode 32 that is sensitive at the same wavelength as the optical-to-electric power converter's signaling transmitter diode 60; a monitor photodiode 28 that is sensitive at the same wavelength as the power lasers 26; optics 34 to image a fraction of the outgoing light 90 onto the photodiode 28; a CPU 22 that controls the power lasers 26; and software (not shown) that accounts for the power in the light beam 90.

In this embodiment, camera 24, illumination diode 30, signal receiving photodiode 32, and alignment laser 38, all are mounted substantially coaxially with light 90. In one embodiment, their field of view is substantially similar to and larger than that of laser(s) 26. This facilitates alignment and use in the safety subsystem. In one embodiment, at 20 meters, their field of view should be approximately four times that of laser(s) 26. The illumination diode 30 can be a near-IR VCSEL, such as the 850 nm VCSELs made by Truelight Corporation of Taiwan, for example. If a higher power is desirable for a particular application, 808 nm edge emitter lasers can be used, such as those available from Alfalight of Madison, Wis. The optical-to-electric power converter's transmitter diode 60 can be a collimated red VCSEL, for example. Thus, the signal receiving photodiode 32 can be a silicon photodiode, for example.

The monitor photodiode(s) 28 can be a germanium photodiode. In one embodiment, the monitor photodiode 28 is mounted close to laser(s) 26 such that it receives the back-reflection from lens(es) 34. Alternatively, a beam splitter can be used.

CPU 22 can be any standard CPU sufficient to handle the data from the camera 24 and the diodes 28, 32. For example, an ARM7-based microprocessor at greater than 50 MHz is preferred.

In the embodiments illustrated in FIGS. 2 and 3, there is free space between the transmitter assembly 20 and the optical-to-electric power converter 50. In the embodiment shown in FIG. 2, light 90 does not point in the direction of optical-to-electric power converter 50 because obstruction 92 is in the path. Between the transmitter assembly 20 and the optical-to-electric power converter 50, there is at least one mirror 42 to redirect the light. In one embodiment, mirror 42 is a small (75 mm×75 mm) mirror affixed to a pan and tilt mechanism 44, which can be similar to pointing mechanism 36. During installation, alignment laser 38 can be turned on and mechanism 44 can be used to steer light 90. When proper alignment is attained, the pan and tilt mechanism 44 can be locked in place. In one example, the system illustrated in FIG. 2 can be used in a person's living room to illuminate a light attached to the ceiling, wherein the load is approximately 20 Watts. One of ordinary skill in the art will recognize that devices having more or less power requirements can also be powered without departing from the principles of the invention described herein.

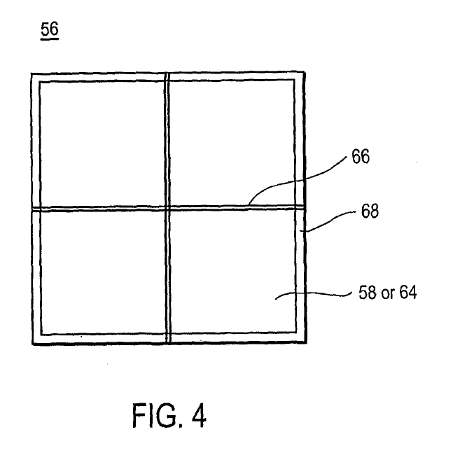

FIG. 2 also shows one embodiment of an optical-to-electric power converter 50, optionally with an indicium on its front surface. The indicium will be described below with reference to FIG. 4. In this embodiment, optics 58 focus light 90 through diffusion layer 64, and onto power conversion photodiode(s) 54. In one embodiment, all optics in the wireless power beaming system are coated for 1400 nm light. In one embodiment, optics 58 includes a Fresnel lens. In some implementations, the optics 58 focus down onto the photodiodes at a rate that exceeds 10:1.

The optical-to-electric power converter 50 includes one or more photodiodes 54. The design of photodiodes 54 depends in part on the nature of the load. For example, for efficient high-power conversion, Indium Phosphide diodes such as those from JDS-Uniphase can be used. In one embodiment, Indium Phosphide diodes are used with one or more lenses for focus-down, for example for powering a television. In another embodiment, for example for powering a cell phone, thin film photodiodes can be used with no focus down. The power conversion photodiode(s) 54 can be a GaSb photodiode(s) as provided by EdTek, Incorporated, in one embodiment. In another embodiment, it may be useful to beam power at approximately 800 nm to silicon photovoltaic diodes. When more than one diode is used, the parallel-series arrangement of the diodes determines the output voltage and current.

The optical-to-electric power converter 50 can also include part of the safety subsystem comprising a signaling device 60, an indicium 56, a current and/or voltage circuit 62, a CPU 52 that controls the light source 60, and software (not shown) that accounts for the power in the optical power beam. In a preferred embodiment, the illumination diode 30 is an 850 nm VCSEL and the indicium is made from retroreflective film, such as that from 3M. For safe operation as described above, the current and voltage circuit 62 monitors the power being received. The CPU 52 operates the current and voltage circuit 62 and communicates with transmitter assembly 20 by modulating an IR-LED 60, for example. The CPU can be an 8-bit CPU, such as those made by Microchip. IR-LED 60 can be a 780 nm LED, for example.

Referring now to FIG. 3, an alternative embodiment of a wireless power beaming system is shown. In this arrangement, there are no mirrors in the path between the transmitter assembly 20 and the optical-to-electric power converter 50. This embodiment can be used, for example, in a cafe or office to charge devices such as cell phones with a load of approximately 3-5 W or laptops with a load of approximately 30-50 W. In the example of FIG. 3, transmitter assembly 20 is attached to the ceiling and pointing downward, but other orientations of the system are also possible. In this application, thin film diodes may be more desirable than bulk diodes to serve as the power conversion photodiode(s) 54 for cost and size reasons. Also, in contrast to the example embodiment shown in FIG. 2, optics 58 are not used and the optical system has no focus-down in the embodiment shown in FIG. 3. Thus, in FIG. 3, optical diffusion layer 64 is the front surface.

In the example of FIG. 3, devices having optical-to-electric power converters 50, such as cell phones, can be moved. To locate devices to deliver power, in this application, pointing mechanism 36 is powered and controlled from the CPU 22. For example, pointing mechanism 36 may be a powered pan-and tilt system. In an alternate embodiment, pointing mechanism 36 may be fixed, and an actuated mirror may be used to alter the beam path and allow the camera to scan.

FIG. 4 illustrates the indicium on the front surface of the optical-to-electric power converter. Indicium 52 has crosshair 66 and perimeter 68. In the preferred embodiments, perimeter 68 is rectangular, but it may also be square, or any other closed shape. In one embodiment, the perimeter 68 surrounds optics 58. In one embodiment, the crosshair 66 is approximately 1 mm wide and the perimeter 68 can be, for example, 1 mm wide or wider. It may be preferable to make the perimeter 68 wider to increase the reaction time in case of a breach of the beam guard. For example, a 10 mm width would assure that a person traveling at 50 m/sec would not be exposed to any radiation at all if the system could shut-down in 200 us.

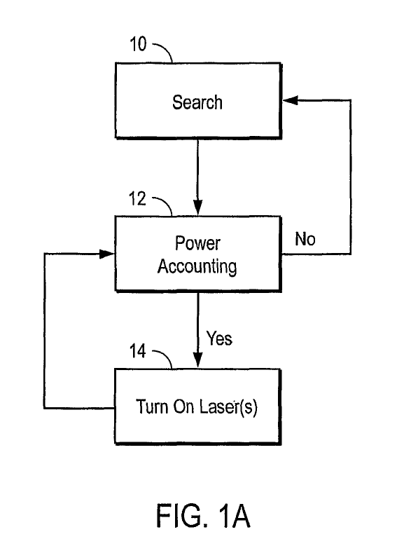

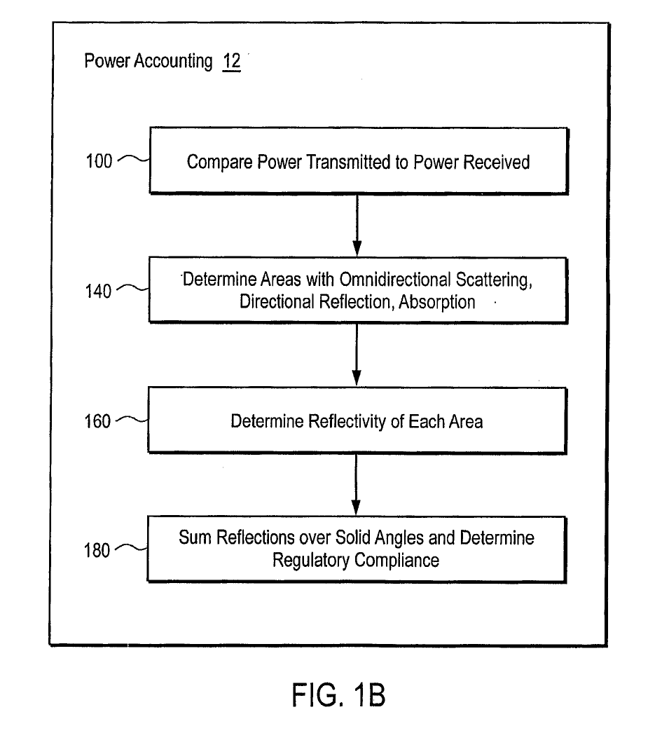

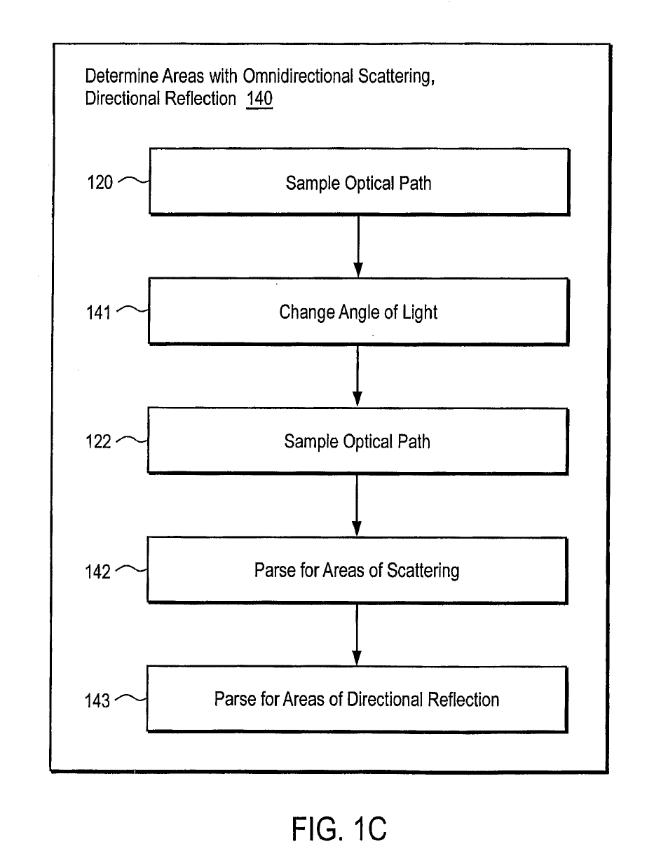

FIG. 1A illustrates an example method of operation in accordance with one embodiment of the safety subsystem. In the search step 10, the transmitter assembly 20 identifies different optical-to-electric power converters to be powered. In one approach, the camera 24 receives images (e.g., which are illuminated by light source 30). The images are parsed by the CPU 22, which looks for an indicium 56 of the optical-to-electric power converter 50. The processing of any step of the method can be accomplished at either CPU 22 or CPU 52, or a combination of both.

If the load is stationary, like a lamp or television, the laser(s) can be aimed at the load and fixed in place. A low-power visible alignment laser 38 can be used for installation as described above. In another embodiment, the load may be anywhere in the room or may move during use, like a cell phone, laptop computer, or vacuum cleaner. In these situations, the camera 24 scans the room to search for the load during the search step 10.

To make the identification of the load easier, the surface of the optical-to-electric power converter 50 can have an indicium 56 that is distinguishable from the surroundings. An example indicium 56 is shown in FIG. 4. In a preferred embodiment, the indicium 56 is a box with a cross-hair. In one implementation, the indicium 56 is made from a retroreflective film to make it clearly visible when the transmitter assembly 20 turns on its illumination diode 30, which operates at a wavelength to which the camera 24 is sensitive. In one embodiment, the camera 24 is a CMOS camera, and a near IR illumination diode 30 is used.

In one embodiment, search step 10 also includes a recognition handshake. When the camera 24 has seen what looks to be an optical-to-electric power converter 50, it supplies a series of pulses of power to the laser(s) 26. If the object seen by the camera 24 is, in fact, an optical-to-electric power converter 50 and no obstruction has entered the path, the optical-to-electric power converter 50 receives the power. In one implementation, the pulses are less than 10 milliseconds duration and of low enough power to not harm humans, for example. Thus, even in the case that the object was misinterpreted, and it is not, in fact, an optical-to-electric power converter 50, the pulses delivered to the object will not contain enough power to harm a human. In one embodiment, the pulses do contain enough energy to power the device to respond as part of the recognition handshake. Thus, even in the case that the device having the optical-to-electric power converter 50 has no remaining power when it is found by the camera 24, the optical-to-electric power converter 50 will be enabled to respond to establish the power link.

In one embodiment, the optical-to-electric power converter 50 can signal on a back information channel. For example, in one embodiment, the CPU 52 blinks a light such as an IR-LED 60. The signal can be a train of optical pulses at greater than 1 MHz, as an example. The signal receiving photodiode 32 receives these signals from the optical-to electric power converter 50. In one embodiment, the optical-to-electric power converter signals its identity, its power requirement, safety information, its dimensions, and/or other information useful for operation. If no return signal is received from the device identified by the camera, the camera continues searching for another indicium 56. Alternatively, the signaling can be initiated in the reverse direction, i.e., from CPU 22 to CPU 52.

In another embodiment, the back information channel is a radio-frequency transmitter, such as 802.11, and the signal receiving photodiode 32 is replaced by a radio signal receiver. In this embodiment, there is a 2-way communication path. This two-way path can be used to send any type of data, including but not limited to safety data. For example, music can be transmitted to audio speakers by modulating the lasers using digital or analog modulation.

Search step 10 can have one of two outcomes: the transmitter assembly 20 either does or does not point at an optical-to-electric power converter 50. In the event that it does not, the system can continue to search until it does.

If the search in step 10 is successful, an optical power accounting is performed in step 12. This step accounts for optical power between a transmitted power of the optical power beam (i.e., optical power transmitted by the transmitter assembly 20) and a received power of the optical power beam (i.e., optical power received by the optical-to-electric power converter 50). One method of performing optical power accounting is described immediately below. Other methods of performing power accounting are described herein with reference to FIGS. 1B and 1C.

In one embodiment, CPU 22 performs the optical power accounting 12 by taking a series of images of the optical-to-electric power converter 50 using camera 24. In one implementation, CPU 22 parses the images from camera 24 seeking object within the perimeter of the optical-to-electric power converter 50, which may be defined by the indicium 56. For example, if indicium 56 is a retroreflective film and there is an area darker or brighter than the surrounding film, it may be an intrusion. A similar method can be used with respect to the beam path as well. In either case, camera 24 is acting as a beam guard. An additional or different beam guarding mechanism may also be employed, such as guard beams 502 described above. An interruption or obstruction in the optical path 90 between the transmitter assembly 20 and the optical-to-electric power converter 50 may be considered a breach of a safe condition. CPU 22 can also examine the images of the surface of the optical-to-electric power converter for scattering reflections and directional reflection. If, for example, Camera 34 detects a bright area on the front surface of optical-to-electric power converter 50, CPU 22 may seek to ascertain whether the reflection is from an omnidirectional scattering source, like dust, or is directional, perhaps retroreflective. Omnidirectional scattering may be accounted for differently than directional reflection because incident light that is omnidirectionally scattered (as from dust) will generally send less light in any one direction than the same incident light reflected directionally (as from oil or water). In situations where the front surfaces of the detector are flat or retroreflective, determining whether surface contaminants or stray reflections are omnidirectional or directional can be important because there is usually no baffle to extinguish these reflections. Reflections anywhere but back along the path to the transmitter assembly 20 may also be a breach of a safe condition for transmission. The transmitter assembly can be designed to extinguish or re-reflect omnidirectionally light that is reflected back toward it from the receiver.

To determine whether scattering is omnidirectional, one can either vary the angle of the illumination or the angle from which the camera sees the reflection. To characterize the reflection, one can provide two or more light sources or two or more cameras. This can be duplicative. Alternatively, a system comprising an actuated mirror can be used as follows: If the camera (or light source) at the transmitter is also actuated and can be pointed directly at the receiver, while the light source (or camera) sees the receiver through a different optical path, for example using the mirror, two angles to view the receiver are available, one by the direct path between the transmitter and receiver, the other by the path via the mirror. Two angles to view the receiver can also be achieved using two or more actuated mirrors in the system. Generally, if the amount of reflected light detected from a point on the surface of the receiver is the same from two different angles, the scattering can be assumed to be dispersive, that is, largely independent of incident angle. This type of dispersive reflection will be referred to herein as omnidirectional. As will be recognized by one of skill in the art, the term “omnidirectional” reflections refers to reflections dispersed over the solid angle associated with one half of the sphere. In one embodiment, the light source is modulated to remove any noise or background in the signal.

In one embodiment, CPU 22 pulses laser(s) 26, and optical-to-electric power converter 50 receives the pulses. Current and/or voltage circuit 62 provides data to CPU 52 on how much power was received by power conversion photodiode(s) 54, including possibly amount of light and uniformity. Because power conversion photodiode(s) 54 usually have slow response times, it may be useful to reflect some of the power beam to a faster detector (not shown). The optical-to electric converter 50 can signal this information to the CPU 22 which has data from its own monitor photodiode(s) 28 on the optical power beamed from laser(s) 26. CPU 22 can make a safety assessment based on the comparison of the information from CPU 52 and monitor photodiode(s) 28. The safety assessment determines whether the system is complying with FDA or other regulations. For example, the CPU 22 may signal a safe condition for transmission only if all optical power is accounted for within the applicable regulatory standards.

In one embodiment, once a device having an optical-to-electric power converter 50 is identified, a baseline of the system is established, and then is continuously updated. Thus, in one embodiment, optical power accounting 12 runs continuously. When the power emitted by the transmitter assembly 20 cannot be accounted for as received by the optical-to-electrical converter 50 nor reflected from the optical-to-electric converter 50 back along the path 90 to the transmitter assembly 20, by process of elimination, the power is assumed to have escaped the hot zone of the system and may harm people or items in the environs of the system. Thus, safe conditions for transmission can be established to set the acceptable levels of this escaped power. If the power escaped omnidirectionally rather than directionally, its disposition in space will be different and generally safer. If the power accounting results in a determination that safe conditions are met, the lasers 26 continue to transmit the optical power beam. Otherwise, corrective and/or safety measures are taken. During system bring up, if a safe condition is breached, the lasers 26 are not turned on. The method may return to search 10 again. When the optical power accounting 12 succeeds (i.e., the safe condition is established), the lasers are turned on in step 14.

In one embodiment, the laser(s) 26 are on watchdog timers. The lasers 26 can be designed to turn off rapidly and automatically if the CPU 22 does not confirm within consecutive short windows of time that they should remain on. They preferably should be switched off quickly enough to avoid possible injury to humans. Alternatively, the system can be configured so that the CPU 22 can turn the one or more lasers 26 off. In either case, responsive to a breach of a safe transmission condition, the conversion of electricity to an optical power beam is rapidly ceased.

Depending on the application, safe conditions can be breached in different ways. For example, a failure of the back information channel may be considered a breach of a safe transmission condition. A decrease in received power over time, where the transmitted power is not decreasing correspondingly, may be considered a breach of a safe transmission condition. Failure to adequately and safely account for lost light (including, for example, light specularly reflected and/or scattered from the optical-to-electric power converter) and detection of obstructions may also be considered to be a breach of a safe transmission condition. Other examples will be apparent.

FIG. 1B shows a detailed example of a power accounting method 12, in accordance with one embodiment. In step 100, the power transmitted is compared to the power received. Note that the comparison may be performed by CPU 22 of the transmitter 20 or by CPU 52 of the receiver. In one embodiment, to maintain safety, first, the transmitter communicates the amount of light to be transferred to the receiver. The amount transmitted can be sampled in real time by a monitor photodiode 28. If the amount received by the receiver 50 changes to an unexpected value, the receiver 50 can signal a fault or breach of a safe condition, and the transmitter 20 can stop transmitting. A differentiating filter within the receiver 50 or alternatively within the transmitter 20 can also be used to detect a change in received power as well as absolute values. Comparing the power transmitted by the transmitter assembly 20 to the power received by receiver 50 in step 100 indicates what light is being absorbed and, to within the bounds of the efficiency of the photodiodes of the receiver 50, what amount of power is being emitted as heat. In step 100, a check is made to determine how much power the surfaces of the system are reflecting. Step 100 can also be useful to run as part of the handshake in the search step 10, in some embodiments.

In step 140, the areas with omnidirectional scattering, the areas with directional reflection, and the areas of absorption are determined. More detail regarding the processes for determining these areas is provided with reference to FIG. 1C.

In step 160, the reflectivity of each area is determined. By determining the intensity of the light transmitted and that received by a camera viewing the surface of the device, the reflectivity of the area can be determined. If an area is dark under perpendicular illumination and the camera is perpendicular, or if the front surface is retroreflective, it is determined that absorption is occurring.

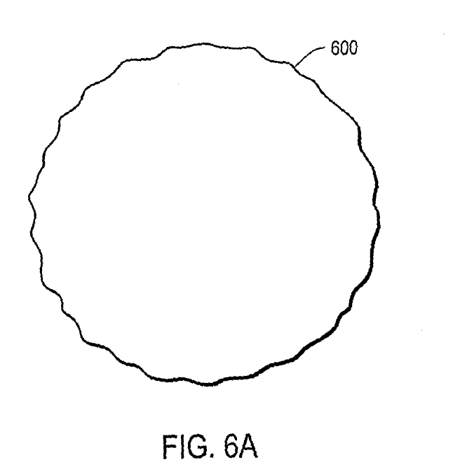

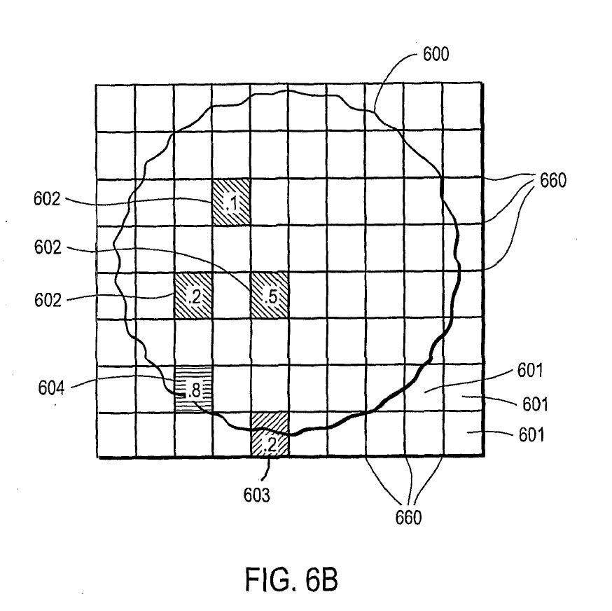

In step 180, the reflections over solid angles are summed to determine regulatory compliance. Summing over each area, the reflected power from a given power of a power beam is calculated for each solid angle, as described in the U.S. Code of Federal Regulations or other regulatory documents. If reflection cannot be determined to be within the limit by a predetermined margin, a fault or breach of a safe condition will be signaled, and the power beam can be turned off. A method of summing over each area is described below with reference to FIGS. 6A and 6B.

In some embodiments, defects in the mirrors 42 and the optics of the transmitter 20, for example lens 34, can be treated as occurring at the receiver 50. This is the conservative, or “worst-case scenario” approach. Alternatively, reflections from these locations out of the hot zone of the system can be treated separately and separate determinations can be made. Regardless of how the calculations are made, if a system becomes too dirty or misaligned to function with certain safety, a fault or breach is signaled and the power beam can be turned off or not turned on.

FIG. 1C shows a detailed example method of determining areas with omidirectional scattering or directional reflection 140, in accordance with one embodiment. In step 120, the optical path is sampled. In one embodiment, the optical path is sampled as follows: A first picture is taken of the receiver (or mirror, or transmitter) without illumination. Then the receiver is illuminated with a known intensity of light. A second picture is then taken of the illuminated receiver. The first picture (un-illuminated) is subtracted from the second picture (illuminated). Alternatively, the illuminated picture may be taken before the un-illuminated picture. A particular order of pictures is not required, but the pictures should preferably be taken close in time, as levels of background light are unlikely to change much in a short period. Low-frequency changes, such as those caused by fluorescent lights, are common. In another embodiment, another method to remove background is to use a bandpass filter in front of a camera and a matched illumination of the receiver. For example, the organic dyes used in IRDA filter plastic can be used for bandpass filters for illumination at wavelengths from approximately 800 nm to 100 nm.

In step 141 the angle of light is changed. In one embodiment, the angle of the light is changed versus the receiver, or the angle at which the camera views the receiver can be changed, for example by using a mirror or by using two light sources. In one embodiment, one light source and the camera are at a zero-angle to the receiver and the other light is at a high angle. In the case that the receiver is retroreflective, the zero-angle may be less important because regardless of where the light source is, the reflection will retroreflect to the source.

In step 122, the optical path is sampled, for example, as described above with reference to step 120.

In step 142, the images are parsed for areas of scattering. Areas where the camera sees approximately the same amount of light from the two angles are areas of scattering. Generally, the amounts of light seen by the camera should reflect the distance and solid angle. The distance can be determined by the size of the image of the receiver or marks on the receiver in the camera or any similar scaling method. Similar methods may also be used to assure that the receiver is perpendicular to the beam. The solid angle is calculated form the f-number of the camera and the distance. In general, the angles will be small and the signals will be low.

In step 143, the images are parsed for areas of directional reflection. Areas where the camera sees distinctly different amounts of light, especially when illumination from very near the camera produces substantially higher readings than illumination from off angle, are areas of directional reflection. The reflections may be from steam, dust in the free space optical beam path, or a similar reflector not near the receiver. In this case, the most conservative and safest method is to assume the worst case and treat these reflections as directional reflections at the receiver. Note directional reflection may be reflection back to the transmitter assembly 20.

In one embodiment, any mirror 42 in the beam path of the system is also tested by the above method. In particular, a mirror 42 may have a defect or area of absorption that hides what is happening later in the optical path (further from the transmitter assembly 20). This may cause a safety fault, or the occlusion may be sufficiently small or located so that it cannot cause a fault. By slightly moving the mirror, occurrences behind the occlusion may be accounted for. In one embodiment, the transmit optics are also tested by the above method, provided a mirror is available.

In one variation, because dirt and some contaminants on the system components are sable over time and other contaminants, like steam or dust in the air, may not be, it can be useful to record areas of known contamination on the surfaces for ease of calculation.

In one embodiment, once a device having an optical-to-electric power converter 50 is identified, a baseline of the system is established and then continuously updated. The amount of power being transmitted can be sampled in real-time using the monitor photodiode 28. The CPU 52 of the receiver 50 can communicate the amount of power that has been received using a back channel communication. For example, in one embodiment, the CPU 52 blinks a light such as an IR-LED 60. The signal can be a train of optical pulses at greater than 1 MHz, as an example. The signal receiving photodiode 32 receives these signals from the receiver 50. If the amount received changes to an unexpected value, the receiver 50 should signal a fault and the transmitter should shut down. A differentiating filter can be used for this as well as testing for an absolute value.

FIG. 6A illustrates an arbitrary surface 600 that for the purposes of calculating reflections has been divided into events as shown by the grid lines 660 of FIG. 6B. In on embodiment, the events correspond to pixels in an image and the arbitrary surface 600 corresponds to a surface of receiver 50. An event outside of surface 600, such as event 601 is an event outside of the receiver 50. The events outside of the surface 600 contribute nothing to the reflection calculation. Omnidirectional scattering event 602 has been designed to reflect omnidirectionally or has been determined to have contamination that causes omnidirectional scattering. The numbers “0.1”, “0.5”, and “0.2” refer to the reflectivity of the arbitrary surface 600 at these events, where “0.0” indicates no reflection, “0.5” indicates 50% reflection, etc. Retroreflective scattering event 603 has been designed to retroreflect or may, in an unlikely case, have been contaminated to retroreflect. Directionally reflecting event 604 is an area where reflection is assumed to be according to the rule that the incident angle versus the normal is equal and opposite of the reflected angle. In one embodiment, the algorithm that determines regulatory compliance calculates the amount of light at points in space along a cylinder (or closed surface) defined by the hot zone. It may not be necessary to calculate for points far from the surface because the intensity of reflected light will disperse at greater distances.

To illustrate the calculation in accordance with one embodiment, assume each event is 1 sq. mm and 1 mW/sq mm is incident. The light from omnidirectional scattering event 602 is characterized as 1 mW multiplied by 0.1 or 0.5 or 0.2, divided by 4πr², where r is the distance from the event to the point of calculation. The light from retroreflective scattering event 603 may be characterized approximately as 0 outside the hot zone—assuming it is completely extinguished after it returns to the transmitter assembly 20. In fact, to account for diffraction and for the fact that it is unlikely that the retroreflector will be perfect, in some cases a small omnidirectional reflected value may be added to the calculation to add a margin of safety. The light from directionally reflective event 604 is calculated as 0 where it is not reflected and 1 mW multiplied by 0.2 divided by sin theta, where theta is the angle of reflection. Because there may be some uncertainty in theta, and because of diffraction, it may be useful to arbitrarily vary theta about a known angle. By summing these values around the hot zone, and then comparing the results with the allowed regulatory values, a determination can be made as to whether the system is in compliance with the regulatory values. In some embodiments, a margin of safety is built in below the regulatory values to account for a margin of error in the measurements and calculations

Although the description above contains many specifics, these should not be construed as limiting the scope of the invention but as merely providing illustrations of some presently preferred embodiments of this invention. For example, the sequence of steps in the methods described may be altered. The positions of some of the elements may be shifted. Efficient light sources at very short eye-safe wavelengths may become available. Different loads require different combinations of elements for maximum usability and minimum cost.

The present invention has been described in particular detail with respect to several possible embodiments. Those of skill in the art will appreciate that the invention may be practiced in other embodiments. First, the particular naming of the components and capitalization of terms is not mandatory or significant, and the mechanisms that implement the invention or its features may have different names, formats, or protocols. Also, the particular division of functionality between the various system components described herein is merely exemplary, and not mandatory; functions performed by a single system component may instead be performed by multiple components, and functions performed by multiple components may instead performed by a single component.

Some portions of above description present the features of the present invention in terms of processes and symbolic representations of operations on information. These algorithmic descriptions and representations are the means used by those skilled in the data processing arts to most effectively convey the substance of their work to others skilled in the art. These operations, while described functionally or logically, are understood to be implemented by computer programs. Furthermore, it has also proven convenient at times, to refer to these arrangements of operations as modules or by functional names, without loss of generality.

Unless specifically stated otherwise as apparent from the above discussion, it is appreciated that throughout the description, discussions utilizing terms such as “determining” or the like, refer to the action and processes of a computer system, or similar electronic computing device, that manipulates and transforms data represented as physical (electronic) quantities within the computer system memories or registers or other such information storage devices. Certain aspects of the present invention include process steps and instructions. It should be noted that the process steps and instructions of the present invention could be embodied in software, firmware or hardware, and when embodied in software, could be downloaded to reside on and be operated from different platforms.

The present invention also relates to an apparatus for performing the operations herein. This apparatus may be specially constructed for the required purposes, or it may comprise a general-purpose computer selectively activated or reconfigured by a computer program stored on a computer readable medium that can be accessed by the computer. Such a computer program may be stored in a computer readable storage medium, such as, but is not limited to, any type of disk including floppy disks, optical disks, CD-ROMs, magnetic-optical disks, read-only memories (ROMs), random access memories (RAMs), EPROMs, EEPROMs, magnetic or optical cards, application specific integrated circuits (ASICs), or any type of media suitable for storing electronic instructions, and each coupled to a computer system bus. Furthermore, the computers referred to in the specification may include a single processor or may be architectures employing multiple processor designs for increased computing capability.

The scope of this invention should be determined by the appended claims and their legal equivalents, rather than by the examples given.

What is claimed is:

1. A transmitter assembly for optically transmitting power through free space to a device requiring electrical power and having an optical-to-electric power converter, the transmitter assembly comprising:
a light source that receives electrical power and converts the electrical power to an optical power beam;
a first optical element that directs the optical power beam through free space to the optical-to-electric power converter of the device; and
a safety subsystem that actively limits optical power beam reflections beyond a hot zone to be within a regulatory limit.

2. The transmitter assembly of claim 1, wherein the safety subsystem actively limits optical power beam reflections in real time.

3. The transmitter assembly of claim 1, wherein the hot zone comprises a path of the power beam between the transmitter assembly to the optical-to-electric converter plus an adjacent buffer area.

4. The transmitter assembly of claim 1, wherein the safety subsystem comprises a camera having a field of view including a path of the optical power beam to the device.

5. The transmitter assembly of claim 1, wherein the safety subsystem comprises a photodetector located proximate to the light source that monitors the power level of the optical power beam transmitted by the transmitter assembly.

6. The transmitter assembly of claim 1, wherein the safety subsystem comprises a beamsplitter that directs a fraction of the power beam to a monitor photodiode.

7. The transmitter assembly of claim 1, wherein the safety subsystem comprises a processor that controls the light source based on a power of the optical power beam transmitted by the transmitter assembly and on a power of the optical power beam received by the device.

8. The transmitter assembly of claim 1, wherein the light source comprises at least one laser that produces an optical power beam at a wavelength longer than 1400 nm.

9. The transmitter assembly of claim 1, wherein the optical power beam has a power density of at least one milliwatt per square millimeter.

10. The transmitter assembly of claim 1, further comprising:
a two-axis mechanical system for directing the optical power beam through free space to the optical-to-electric power converter of the device.

11. A system for optically transmitting power through free space to a device requiring electrical power, the system comprising:
an optical-to-electric power converter for producing electrical power for a device;
a transmitter assembly located remotely from the optical-to-electrical power converter, comprising
a light source that receives electrical power and converts the electrical power to an optical power beam;
a first optical element that directs the optical power beam through free space to the optical-to-electric power converter of the device; and
a safety subsystem that actively limits optical power beam reflections beyond a hot zone to be within a regulatory limit.

12. The system of claim 11, further comprising a beam guard.

13. The system of claim 12, wherein the beam guard comprises a camera.

14. The system of claim 13, wherein the camera monitors light reflected from a surface of the optical-to-electric converter.

15. The system of claim 11, wherein the safety subsystem comprises:
a signaling device connected to the optical-to-electric power converter, that transmits a signal; and
a signal receiver connected to the transmitter assembly, that receives the signal.

16. The system of claim 15, wherein the safety subsystem further comprises an information channel from the optical-to-electric power converter to the transmitter assembly.

17. The system of claim 16, wherein the information channel provides a received power signal to the transmitter assembly in real-time, or a transmitted power to the optical-to-electric power converter in real-time, or both.

18. The system of claim 11, wherein the safety subsystem comprises one selected from the group consisting of an electrical current and voltage detector and a beamsplitter providing a fraction of the power beam to a photodiode, to monitor the power of the power beam received by the optical-to-electric power converter.

19. The system of claim 11, further comprising a mirror that redirects the optical power beam from the first optical element to the optical-to-electric power converter.

20. The system of claim 11, wherein the optical-to-electric power converter comprises a photo diode.

21. The system of claim 11, further comprising a retroreflective surface proximate to a surface of the optical-to-electric power converter.

22. The system of claim 11, wherein the optical-to-electric power converter comprises power conversion elements that are angled with respect to the power beam, and wherein directional reflections from the surfaces of the angled power conversion elements are absorbed by a baffle.

23. The system of claim 11, wherein the safety subsystem actively limits optical power beam reflections in real time.

24. The system of claim 11, wherein the hot zone comprises a path of the power beam between the transmitter assembly to the optical-to-electric converter plus an adjacent buffer area.

25. A method for optically transmitting power through free space to a device requiring electrical power, the method comprising:
converting an optical power beam transmitted through free space to electrical power for the device;
performing an optical power accounting between a transmitted power of the optical power beam and a received power of the optical power beam; and
responsive to a power accounting that signals a safe condition for transmission:
continuing to convert received electrical power to the optical power beam; and
continuing to transmit the optical power beam through free space to the device.

26. The method of claim 25, wherein the step of performing an optical power accounting is performed in real-time.

27. The method of claim 25, wherein performing an optical power accounting comprises:
tracking in real-time the transmitted power of the optical power beam; and
tracking in real-time the received power of the optical power beam.

28. The method of claim 25, further comprising:
responsive to an optical power accounting that signals a breach of safe condition for transmission, switching off the optical power beam quickly enough to avoid exceeding regulatory limits for human exposure.

29. A method of operating a free space optical power beaming system, the method comprising:
determining a first amount of power transmitted by a transmitter assembly as an optical power beam;
determining a second amount of power from the beam received by a receiver;
determining a third amount of power from the beam reflected outside of a hot zone; and
responsive to the third amount of power exceeding a regulatory limit, ceasing transmission of the optical power beam.

30. The method of claim 29, wherein the third amount is determined in part by characterizing reflections of the beam as directional or as omnidirectional.

31. The method of claim 29, further comprising determining a fourth amount of power reflected by the receiver back to the transmitter assembly.

32. A method of determining direction and intensity of reflection from an illuminated surface, the method comprising:
examining a surface of a device from at least two angles with respect to incident light;
comparing a first amount of reflected light observed from a first of the at least two angles to a second amount of reflected light observed from a second of the at least two angles; and
responsive to determining the amount of reflected light is independent of incident angle, characterizing the reflected light as omnidirectionally scattered.

33. The method of claim 32, wherein at least one of the at least two angles is obtained using a mirror.

34. The method of claim 32, further comprising:
responsive to determining the amount of reflected light is not independent on angle, characterizing the reflected light as directional; and
summing the omnidirectional reflections and directional reflections for a point outside of a hot zone to determine regulatory compliance.

35. A method of transmitting power through free space to a device requiring electrical power and having an optical-to-electric power converter, the method comprising:
identifying an optical-to-electric power converter;
transmitting a power beam pulse to the optical-to-electric power converter; and
receiving a response from the optical-to-electric power converter, wherein the response was powered in part from the transmitted power beam pulse.

36. The method of claim 35, wherein identifying an optical-to-electric power converter comprises a camera identifying an indicium on the optical-to-electric power converter.
